(19) United States
(12) Patent Application Publication
(10) Pub. No.: US 2026/0190450 A1
(43) Pub. Date: Jul. 2, 2026

(54) SILICON-DOPED OXIDE-BASED MATERIAL FOR ADVANCED GATE ELECTRODE APPLICATIONS

(71) Applicant: Taiwan Semiconductor Manufacturing Co., Ltd., Hsinchu (TW)

(72) Inventors: Kai-Chieh Yang, New Taipei City (TW); Chun-Da Liao, Taipei City (TW); Tzu Pei Chen, Taipei City (TW); Wei-Yen Woon, Taoyuan City (TW); Szuya Liao, Zhubei (TW)

(21) Appl. No.: 19/208,864

(22) Filed: May 15, 2025

Related U.S. Application Data
(60) Provisional application No. 63/741,265, filed on Jan. 2, 2025.

(51) Int. Cl. H10D 84/01; H10D 84/85

(52) U.S. Cl. CPC H10D 84/0181; H10D 84/0167; H10D 84/017; H10D 84/851; H10D 84/856

(57) ABSTRACT

A method includes forming a semiconductor region, forming a gate spacer over the semiconductor region, forming a source/drain region aside of the semiconductor region, wherein the source/drain region is of p-type, and forming a gate dielectric over the semiconductor region. The gate dielectric is formed in a space between opposing portions of the gate spacer. A ruthenium oxide layer is formed over the gate dielectric, and acts as a part of a work-function layer of a gate electrode. The method further includes incorporating silicon into the ruthenium oxide layer.

### PRIORITY CLAIM AND CROSS-REFERENCE

This application claims the benefit of the following provisionally filed U.S. Patent application: Application No. 63/741,265, filed on Jan. 2, 2025, and entitled “CFET Gate Electrode,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIG. 2 through FIGS. 16A and 16B are views of intermediate stages in the manufacturing of CFETs in accordance with some embodiments.

FIGS. 17-23 are views of intermediate stages in the manufacturing of gate stacks of CFETs in accordance with some embodiments.

FIGS. 24-25 are profiles of silicon and ruthenium in accordance with some embodiments.

FIGS. 26 and 27 illustrate flow charts for forming CFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Complementary Field-Effect Transistor (CFET) structure and the method of forming the same are provided. Throughout the description, the terms “FET” and “transistor” are used interchangeably. In accordance with some embodiments, ruthenium oxide is used as the work-function layer of the PFETs, and silicon (or silicon oxide) is used to trap the oxygen in the ruthenium oxide, so that the ruthenium oxide is less likely to reduce to elemental ruthenium.

It is appreciated that while Gate-All-Around (GAA) transistors (such as nanostructure-FETs) are discussed, the concept of the present disclosure can also be applied to the formation of other types of transistors such as planar transistors, Fin Field-Effect Transistors (FiNFETs), or the like.

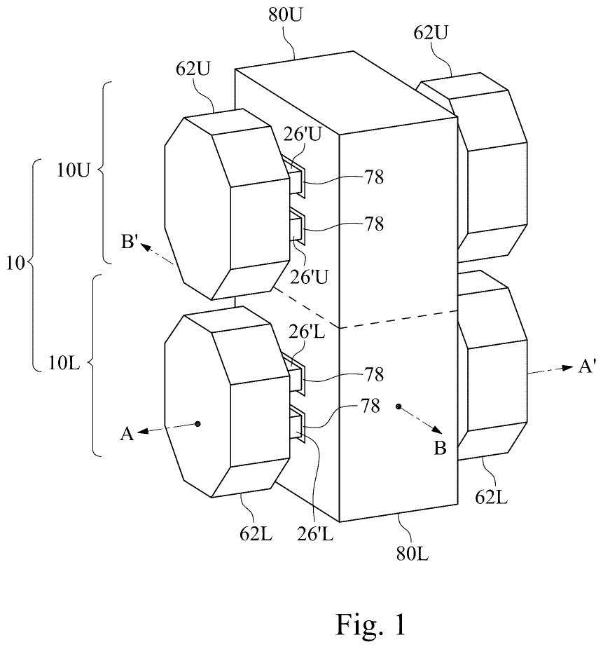

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

Gate dielectrics 78 encircle the respective semiconductor nanostructures 26′. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26′ of a CFET and in a direction of, for example, a current flow between the source/drain regions 62 of the CFET. Cross-section B-B′ is a vertical cross-section that is perpendicular to cross-section A-A′ and along a longitudinal axis of a gate electrode 80 of the CFET. Subsequent figures may refer to these reference cross-sections for clarity.

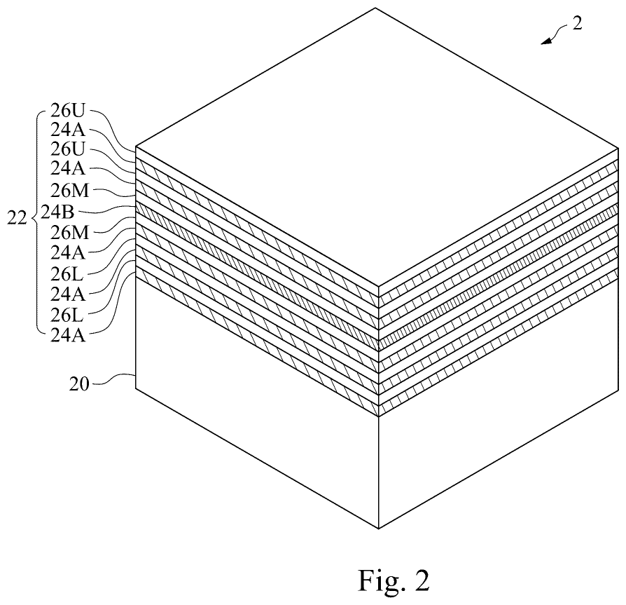

FIGS. 2 through 24A and 24B illustrate the cross-sectional views of intermediate stages in the formation of CFETs (as schematically represented in FIG. 1) in accordance with some embodiments. The corresponding processes are also reflected schematically in the process flow shown in FIG. 33. In subsequent discussion, unless specified otherwise, the figures having digits followed by letter “A” illustrate the vertical cross-sectional views along a similar cross-section as vertical reference cross-section A-A′ in FIG. 1. The figures having digits followed by letter “B” illustrate the cross-sectional views along a similar cross-section as the vertical reference cross-section B-B′ in FIG. 1.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

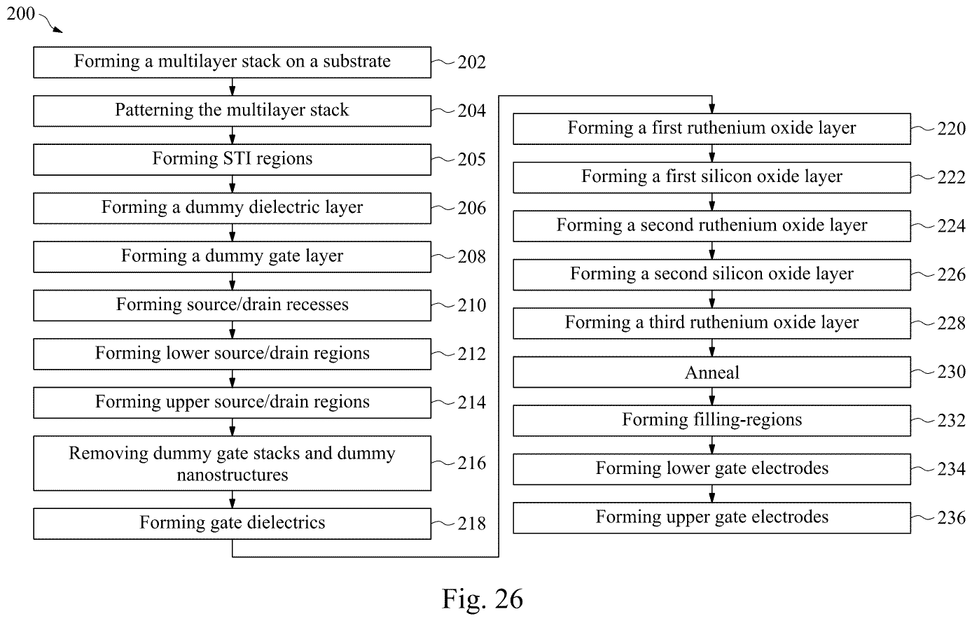

A multi-layer stack 22 is formed over the substrate 20. The respective process is illustrated as process 202 in the process flow 200 as shown in FIG. 26. The multi-layer stack 22 includes alternating dummy semiconductor layers 24 (including dummy semiconductor layers 24A and 24B) and semiconductor layers 26 (including lower semiconductor layers 26L and upper semiconductor layers 26U). Lower semiconductor layers 26L and upper semiconductor layers 26U are for forming a lower FET and an upper FET, respectively.

Appropriate wells (not separately illustrated) may be formed in lower semiconductor layers 26L and upper semiconductor layers 26U. For example, semiconductor layers 26L and 26U may be in-situ doped (when epitaxially grown) and/or implanted to desirable conductivity types.

In the illustrated example, the multi-layer stack 22 includes six of the dummy semiconductor layers 24 and six of the semiconductor layers 26. It should be appreciated that the multi-layer stack 22 may include any number of the dummy semiconductor layers 24 and the semiconductor layers 26. Each layer of the multi-layer stack 22 may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like.

The dummy semiconductor layers 24A are formed of a first semiconductor material, the dummy semiconductor layer 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. The lower semiconductor layers 26L and the upper semiconductor layers 26U may be formed of the same semiconductor material, or may be formed of different semiconductor materials.

In some embodiments, dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than in semiconductor layer 24A.

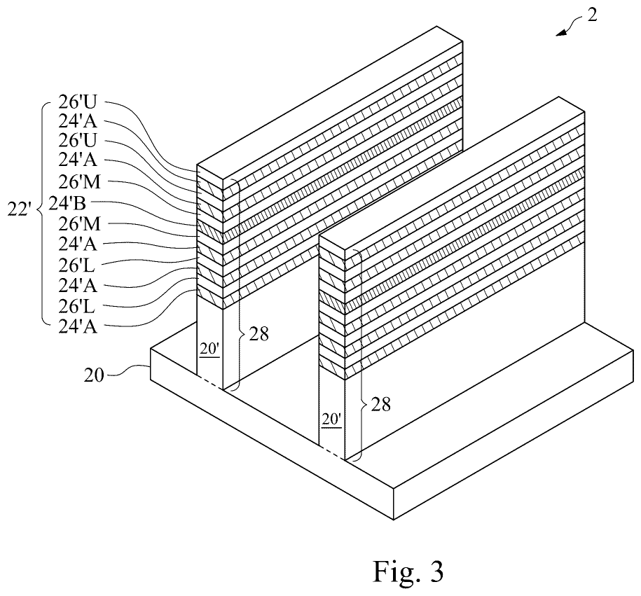

In FIG. 3, multi-layer stack 22 and substrate 20 are patterned to form semiconductor strips 28. The respective process is illustrated as process 204 in the process flow 200 as shown in FIG. 26. Each of semiconductor strips 28 includes semiconductor strip 20′ (the portions of the original substrate 20) and multi-layer stack 22′, which is the remaining portion of multi-layer stack 22. The remaining portions 22′ of multi-layers stack 22 are referred to as nanostructures hereinafter, which are referred to using the corresponding reference number followed by a “′” sign. Accordingly, multi-layer stack 22′ includes dummy nanostructures 24′A, dummy nanostructures 24′B, lower semiconductor nanostructures 26′L, middle semiconductor nanostructures 26′M, and upper semiconductor nanostructures 26′U.

The etching may be performed by any acceptable etch process, such as a Reactive Ion Etch (RIE), Neutral Beam Etch (NBE), the like, or a combination thereof. The etching may be anisotropic. Dummy nanostructures 24′A and dummy nanostructures 24′B may further be collectively referred to as dummy nanostructures 24′. The lower semiconductor nanostructures 26′L and the upper semiconductor nanostructures 26′U may further be collectively referred to as semiconductor nanostructures 26′.

The lower semiconductor nanostructures 26′L will act as channel regions for lower nanostructure-FETs of the CFETs. The upper semiconductor nanostructures 26′U will act as channel regions for upper nanostructure-FETs of the CFETs. The middle semiconductor nanostructures 26′M are the semiconductor nanostructures 26′ that are immediately above/below (e.g., in contact with) the dummy nanostructures 24′B. The middle semiconductor nanostructures 26′M may be used for isolation and may or may not act as channel regions for the CFETs. The dummy nanostructures 24′B will be subsequently replaced with isolation structures. The isolation structures and the middle semiconductor nanostructures 26′M may define boundaries of the lower nanostructure-FETs and the upper nanostructure-FETs.

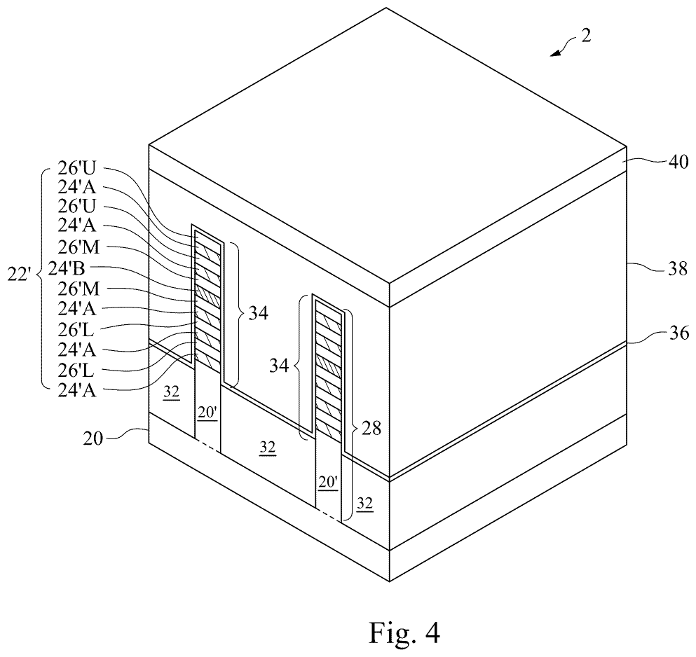

In FIG. 4, isolation regions 32 are formed over the substrate 20 and between adjacent semiconductor strips 28. The respective process is illustrated as process 205 in the process flow 200 as shown in FIG. 26. Isolation regions 32 may include a dielectric liner and a dielectric material over the dielectric liner. Isolation regions 32 are then recessed. Some upper portions of semiconductor strips 28 (including multi-layer stacks 22′) protrude higher than the remaining isolation regions 32 to form protruding fins 34.

Dummy dielectric layer 36 is then formed on the protruding fins 34. The respective process is illustrated as process 206 in the process flow 200 as shown in FIG. 26. Dummy dielectric layer 36 may be formed of or comprise, for example, silicon oxide, silicon nitride, a combination thereof, or the like, and may be deposited or thermally grown according to acceptable techniques.

A dummy gate layer 38 is formed over the dummy dielectric layer 36. The respective process is illustrated as process 208 in the process flow 200 as shown in FIG. 26. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like.

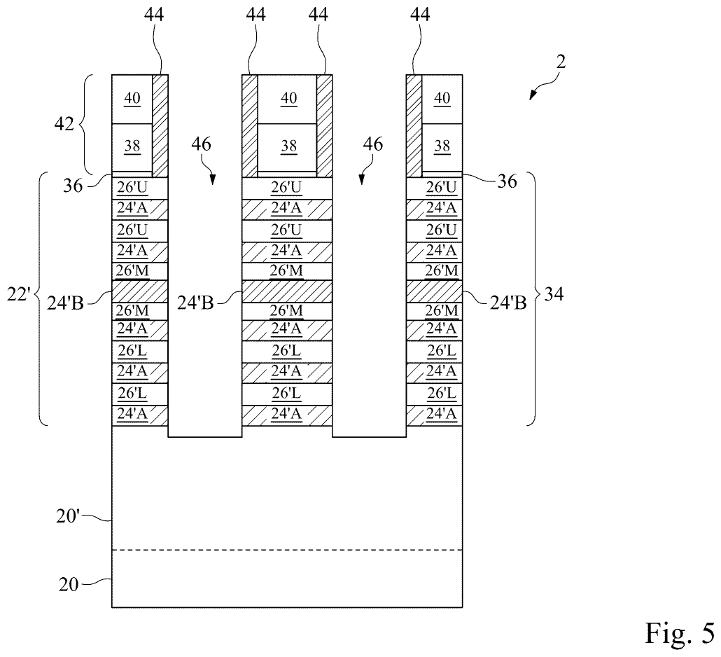

Next, the mask layer 40 may be patterned through photolithography and etching processes to form a mask, which is then used to etch and pattern dummy gate layer 38, and possibly dummy dielectric layer 36. A resulting structure is shown in FIG. 5. The remaining portions of mask layer 40, dummy gate layer 38, and dummy dielectric layer 36 form dummy gate stacks 42.

In FIG. 5, gate spacers 44 are formed over the multi-layer stacks 22′ and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Source/drain recesses 46 are then formed in semiconductor strips 28. The respective process is illustrated as process 210 in the process flow 200 as shown in FIG. 26. The source/drain recesses 46 are formed through etching, and may extend through the multi-layer stacks 22′ and into the semiconductor strips 20′. The bottom surfaces of the source/drain recesses 46 may be at a level above, below, or level with the top surfaces of the isolation regions 32 (FIG. 4). In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

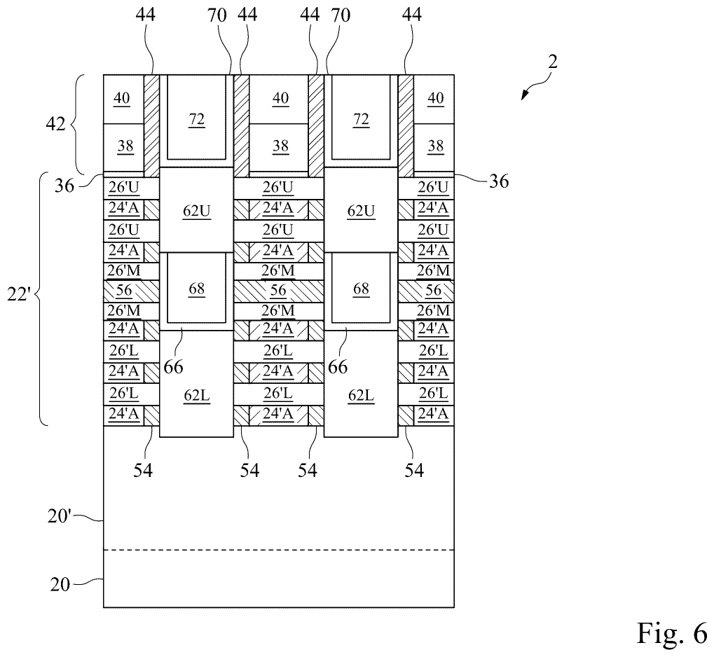

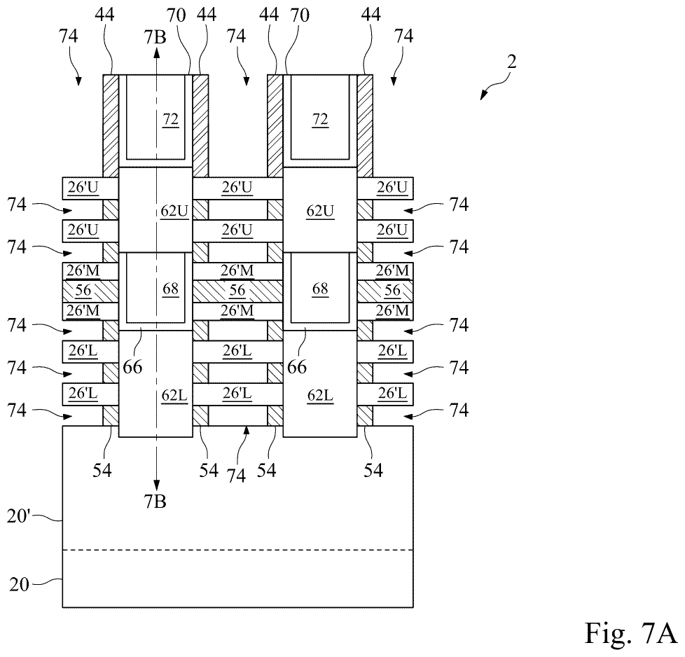

Dummy nanostructures 24′A are then laterally recessed, and a dielectric material is filled into the respective recesses to form inner spacers 54, which are dielectric spacers. The resulting structure is shown in FIG. 6. Dielectric isolation layers 56 are also formed to replace the dummy nanostructures 24′B.

Next, lower epitaxial source/drain regions 62L are formed in the lower portions of the source/drain recesses 46 (FIG. 5). The respective process is illustrated as process 212 in the process flow 200 as shown in FIG. 26. The lower epitaxial source/drain regions 62L are in contact with the lower semiconductor nanostructures 26′L and are not in contact with the upper semiconductor nanostructures 26′U. Inner spacers 54 electrically insulate the lower epitaxial source/drain regions 62L from the dummy nanostructures 24′A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants

A first contact etch stop layer (CESL) 66 and a first ILD 68 are formed. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26′U are exposed.

Next, upper epitaxial source/drain regions 62U are formed in the upper portions of the source/drain recesses 46. The respective process is illustrated as process 214 in the process flow 200 as shown in FIG. 26. The materials of upper epitaxial source/drain regions 62U may be selected from the same candidate group of materials for forming lower source/drain regions 62L, depending on the desired conductivity type of upper epitaxial source/drain regions 62U.

The conductivity type of the upper epitaxial source/drain regions 62U may be opposite the conductivity type of the lower epitaxial source/drain regions 62L. Alternatively stated, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant.

Next, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave hard masks 40 unremoved.

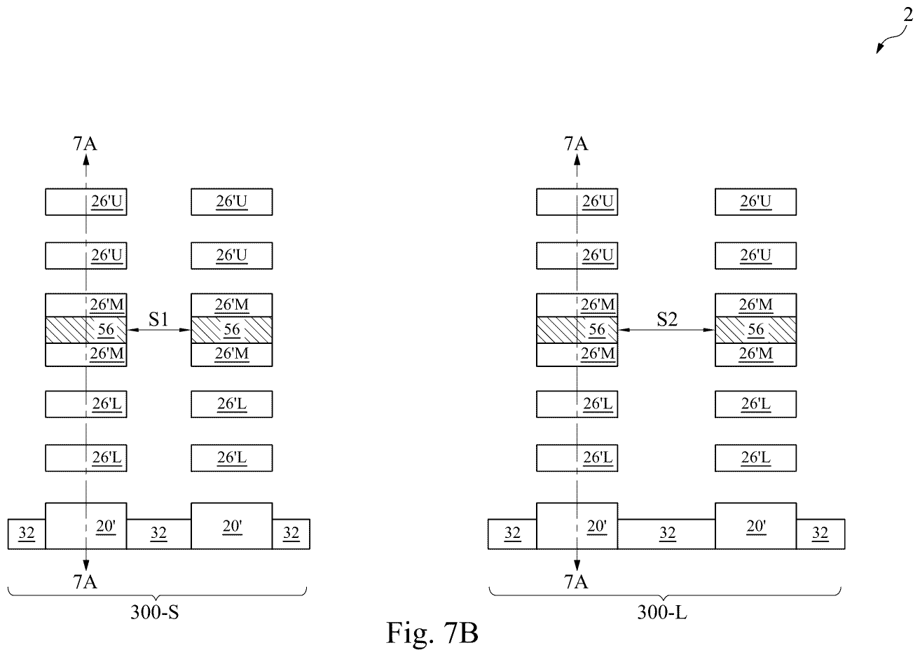

The dummy gate stacks 42 are then removed in one or more etching processes, so that recesses 74 (also referred to as gaps) are formed, as shown in FIGS. 7A and 7B. Each of recesses 74 exposes and/or overlies portions of multi-layer stacks 22′ (FIG. 6). The respective process is illustrated as process 216 in the process flow 200 as shown in FIG. 26.

The remaining portions of the dummy nanostructures 24′A (FIG. 6) are then removed through etching, so that recesses 74 extend between the semiconductor nanostructures 26′. The respective process is also illustrated as process 216 in the process flow 200 as shown in FIG. 26. In the etching process, the dummy nanostructures 24′A is etched at a faster rate than the semiconductor nanostructures 26′, the dielectric isolation layers 56, and the inner spacers 54. The etching may be isotropic. For example, when the dummy nanostructures 24′A are formed of silicon-germanium, and the semiconductor nanostructures 26′ are formed of silicon, the etch process may include a wet etch process using tetramethylammonium hydroxide (TMAH), ammonium hydroxide (NH₄OH), or the like.

FIG. 7B illustrates the structures that may be obtained from cross-section 7B-7B in FIG. 7A. Two device regions 300-S and 300-L are illustrated. Device region 300-S is the region in which neighboring multilayer stacks have small gap S1, and device region 300-L is the region in which neighboring multilayer stacks have a greater gap S2, which is greater than gap S1. Each of the device regions is for forming a CFET including an upper FET and a lower FET. In the illustrated example, the upper FETs are NFETs, and the lower FETs are PFETs. It is appreciated that the present disclosure may be applied to the CFETs in which the lower FETs are NFETs, and the upper FETs are PFETs. The cross-sections shown in FIG. 7A may represent either one or both of the cross-sections 7A-7A in device region 300-S and 300-L.

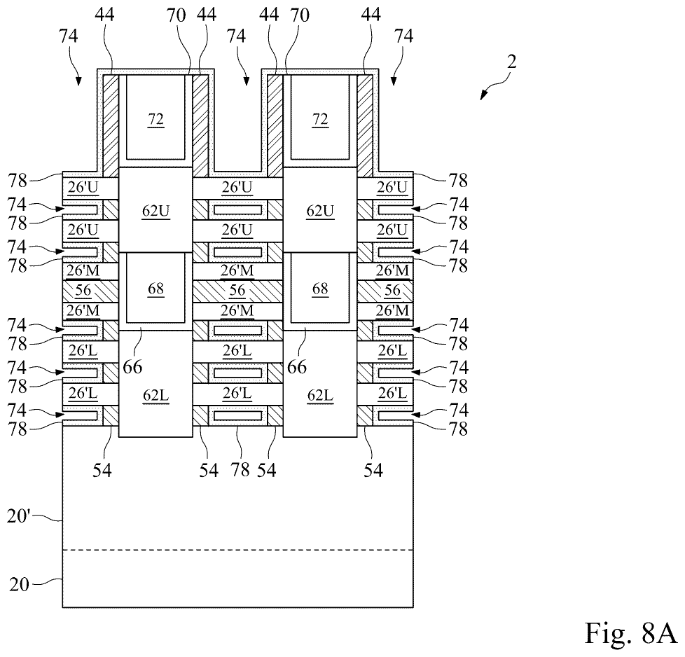

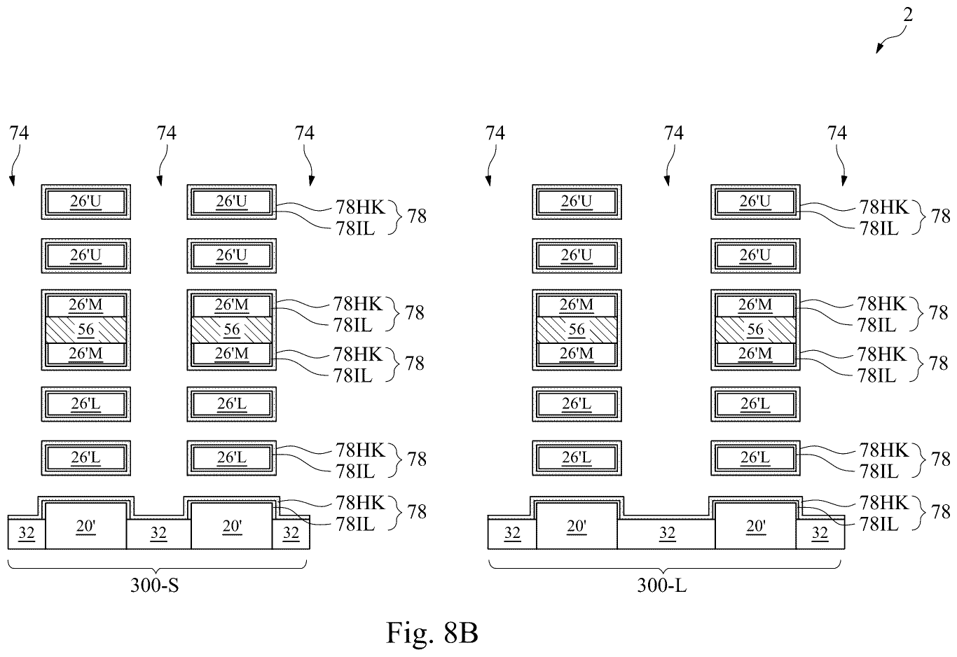

In FIGS. 8A and 8B, gate dielectrics 78 are formed in recesses 74. The respective process is illustrated as process 218 in the process flow 200 as shown in FIG. 26. The gate dielectrics 78 are formed on the exposed surfaces of the exposed features including the semiconductor nanostructures 26′ and the gate spacers 44. The gate dielectrics 78 wrap around all (e.g., four) sides of the semiconductor nanostructures 26′.

Each of the gate dielectrics 78 may include an interfacial layer 78IL, which may include an oxide such as silicon oxide. The gate dielectrics 78 may also include high-k dielectric layers 78HK encircling the respective interfacial layers. The high-k dielectric layers 78HK may be formed of or comprise a metal oxide or a silicate of a metal selected from hafnium, zirconium, barium, titanium, lead, and combinations thereof.

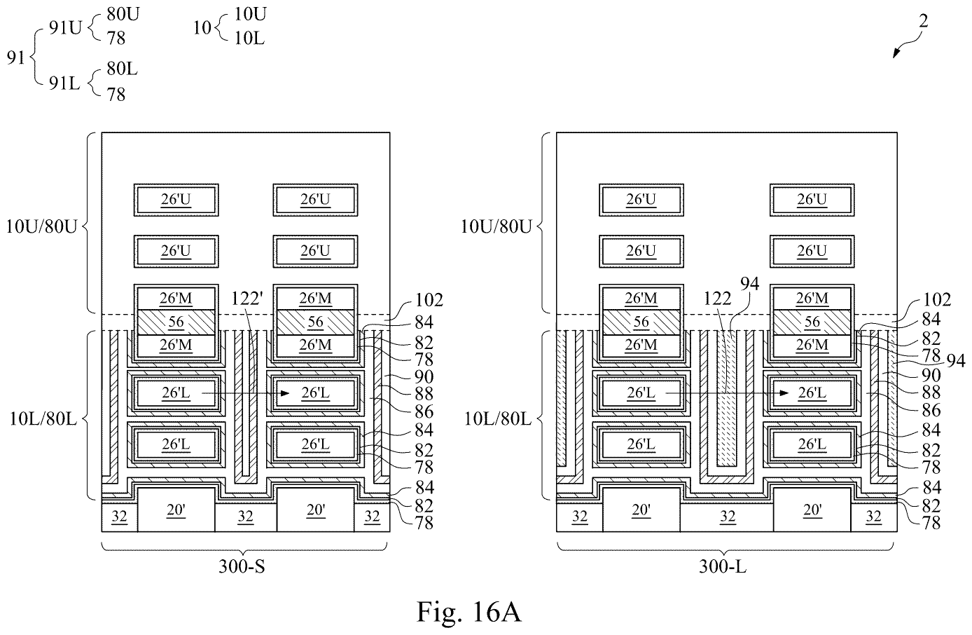

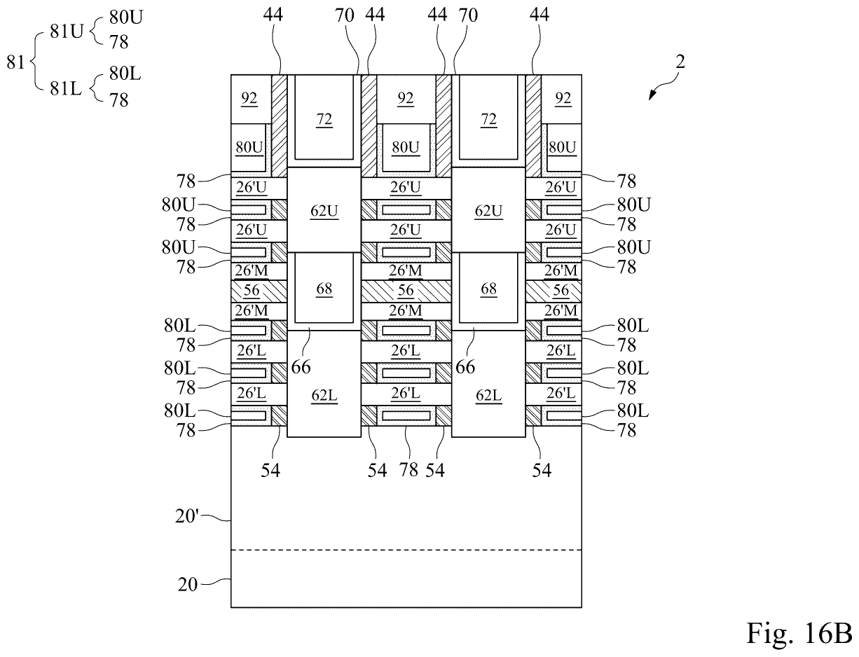

In some embodiments, the interfacial layer 78IL may be formed on the semiconductor nanostructures 26′M/26′L/26′U (as shown in FIGS. 7A and 7B) without being formed on the dielectric layers 56. In subsequent figures, the interfacial layer 78IL and high-k dielectric layers 78HK may be shown collectively as dielectric layers 78, without being illustrated separately. The details of the interfacial layer 78IL and high-k dielectric layers 78HK may be found referring to FIGS. 7A, 7B, and 16B.

The formation methods of the high-k dielectric layers 78HK may be selected from Molecular-Beam Deposition (MBD), ALD, PECVD, and the like. As shown in FIG. 8B, gate dielectrics 78 may encircle nanostructures 26′U, 26M, and 26′L. The gate dielectrics 78 in device regions 300-S and 300-L are formed in common processes.

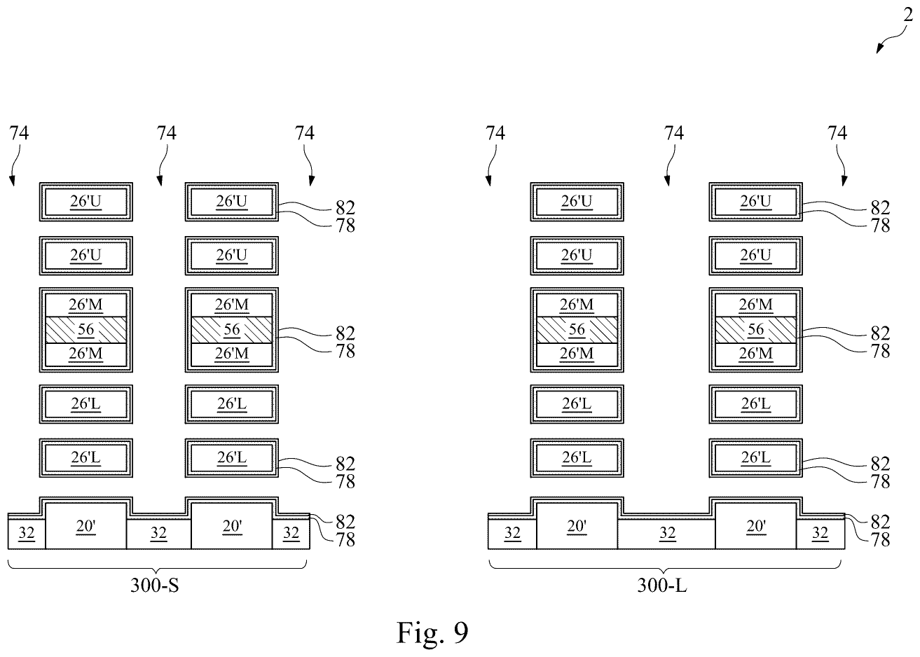

FIGS. 9 through 16A and 16B illustrate the details for forming gate electrodes 80 (including 80U and 80L, FIGS. 16A and 16B) in accordance with some embodiments. Referring to FIG. 9, a ruthenium oxide layer 82 is deposited, and encircles the respective gate dielectrics 78. The respective process is illustrated as process 220 in the process flow 200 as shown in FIG. 26. Ruthenium oxide layer 82 includes a plurality of portions, each encircling one of the gate dielectrics 78. The plurality of portions of the ruthenium oxide layer 82 are also referred to as a plurality of ruthenium oxide layers 82.

In accordance with some embodiments, the deposition of ruthenium oxide layer 82 is performed through a conformal deposition process such as an Atomic Layer Deposition (ALD) process, which includes a plurality of ALD cycles. Each ALD cycle may include pulsing and purging a ruthenium-containing precursor, and pulsing and purging an oxygen-containing precursor.

The ruthenium-containing precursor may be selected from bis(cyclopentadienyl)Ru(II) [RuCp2,Ru(C₅H₅)₂]; bis(ethylcyclopentadienyl)Ru(II); [Ru(EtCp)₂, Ru(C₂H₅C₅H₄)₂]; tris(tetramethylheptane-dionate)Ru(III); [Ru(thd)₃, Ru(C₁₁H₁₉O₂)₃]₁₄; tris(acetylacetonato)Ru (III) [Ru(acac)₃, Ru (C₅H₇O₂)₃, and/or the like.

The oxygen-containing precursor may comprise ozone (O₃), water steam (H₂O), oxygen (O₂), and/or the like. Hydrogen (H₂) may be added into the oxygen-containing precursor. In accordance with some embodiments, ruthenium oxide layer 82 has a thickness smaller than about 1 nm, for example, in the range between about 0.5 nm and about 1 nm.

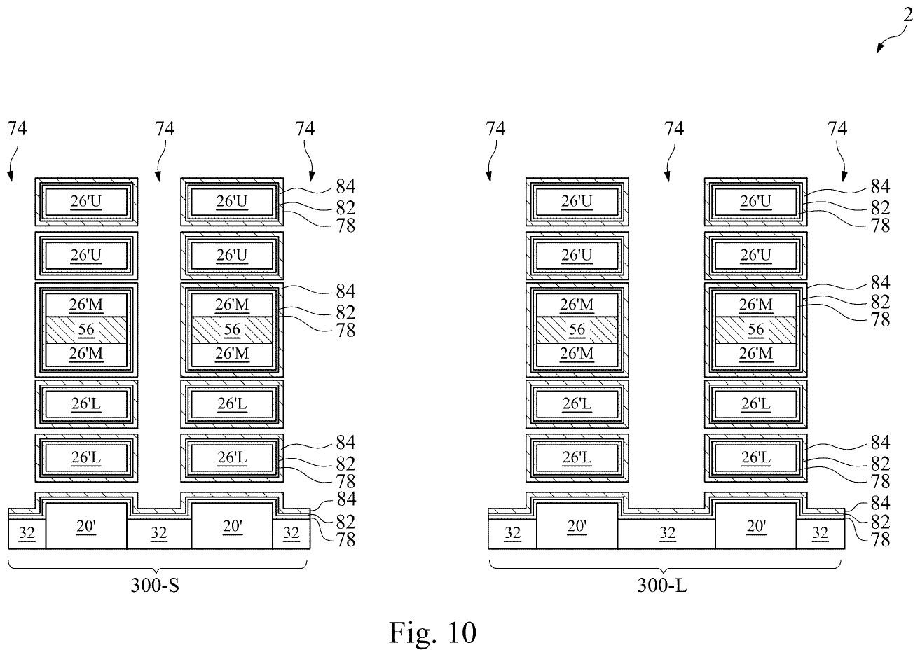

Referring to FIG. 10, silicon oxide layer 84 is formed. The respective process is illustrated as process 222 in the process flow 200 as shown in FIG. 26. Silicon oxide layer 84 may be deposited through soaking the respective wafer 2 in a silicon-containing precursor such as silane, di-silane, or the like. The soaking process may be performed in a chamber, which was originally filled with open air.

The silicon-containing precursor is conducted into the chamber, in which wafer 2 is placed. The pressure in the chamber, due to the conduction of the silicon-containing precursor, may be slightly higher than one atmosphere. A soaking process is thus performed, with the wafer 2 being soaked in the silicon-containing precursor and air. Silicon oxide layer 84 is thus formed.

The pressure of the chamber may be controlled to be not too high, and the soaking time may be controlled to be not too long, so that the resulting work-function layer has an overall silicon atomic percentage smaller than about 10 percent. Otherwise, too much silicon may adversely affect the work function of the resulting work-function layer. In accordance with some embodiments, the pressure of the soaking chamber may be in the range between about 5 torr and about 30 torr, and the soaking time may be in the range between about 1 minute and about 10 minutes. The resulting silicon oxide layer 84 may have a thickness in the range between about 1 Å and about 10 Å.

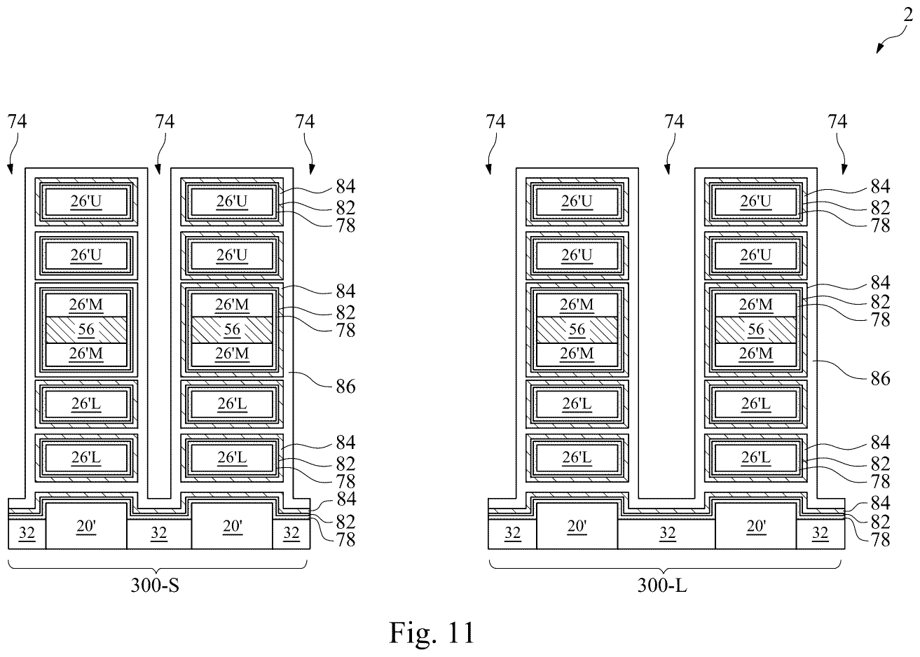

FIG. 11 illustrates the formation of ruthenium oxide layer 86. The respective process is illustrated as process 224 in the process flow 200 as shown in FIG. 26. The formation process may be essentially the same as the formation of ruthenium oxide layer 82, and thus the process details are not repeated herein. In accordance with some embodiments, ruthenium oxide layer 86 has a thickness greater than the thickness of ruthenium oxide layer 82. For example, the thickness of ruthenium oxide layer 86 may be in the range between about 1.5 nm and about 2.5 nm.

In accordance with some embodiments, ruthenium oxide layer 86 may fully fill the spaces between the vertically stacked semiconductor nanostructures 26′. In other embodiments, there are still spacings left unfilled between the vertically stacked semiconductor nanostructures 26′.

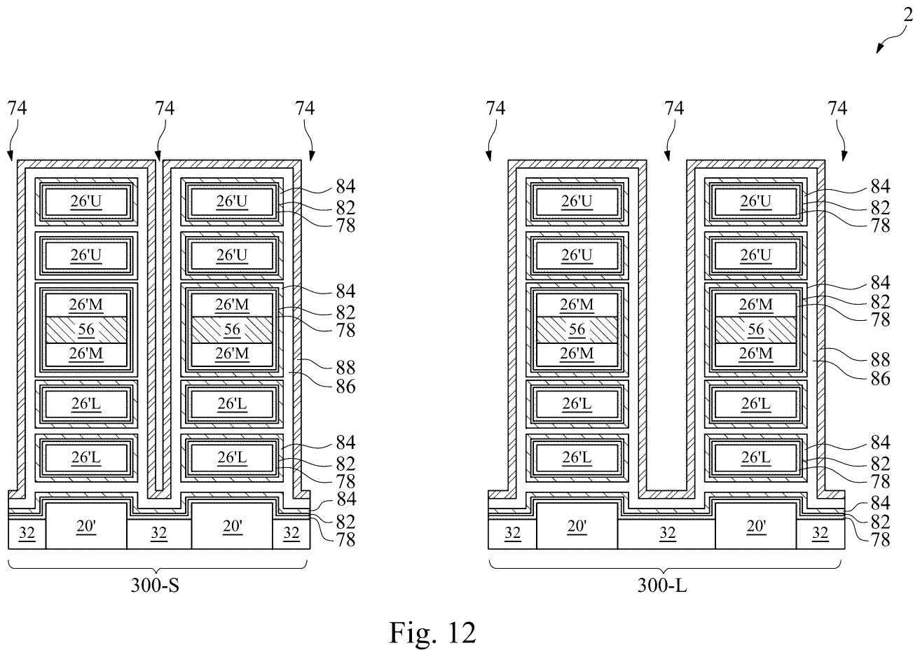

FIG. 12 illustrates the formation of silicon oxide layer 88. The respective process is illustrated as process 226 in the process flow 200 as shown in FIG. 26. The formation process may be essentially the same as the formation of silicon oxide layer 84, and thus the process details are not repeated herein. In accordance with some embodiments, silicon oxide layer 88 has a thickness similar to, greater than, or smaller than, the thickness of silicon oxide layer 84.

In accordance with some embodiments, silicon oxide layer 88 is formed outside of the spaces between the vertically aligned upper semiconductor nanostructures 26′. In other embodiments, silicon oxide layer 88 may also include portions in the spaces between the vertically aligned upper semiconductor nanostructures 26′, and thus may form a plurality of rings in the illustrated cross-section.

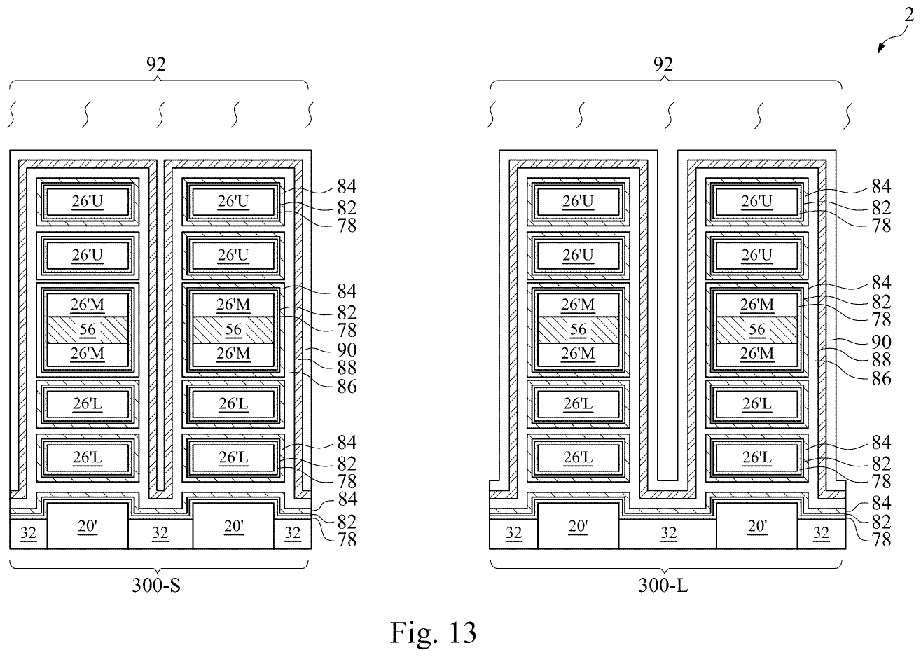

FIG. 13 illustrates the formation of ruthenium oxide layer 90. The respective process is illustrated as process 228 in the process flow 200 as shown in FIG. 26. The formation process may be essentially the same as the formation of ruthenium oxide layer 82, and thus the process details are not repeated herein. In accordance with some embodiments, ruthenium oxide layer 90 has a thickness greater than the thickness of ruthenium oxide layer 82. For example, the thickness of ruthenium oxide layer 86 may be in the range between about 1.5 nm and about 2.5 nm.

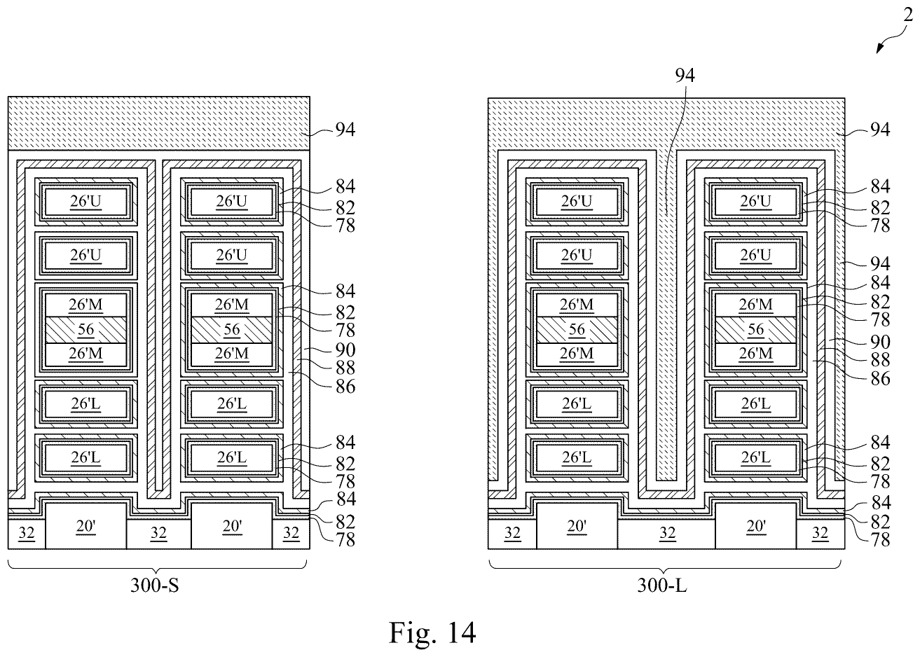

In accordance with some embodiments, the total thickness of ruthenium oxide layers 82, 86, and 90 and silicon oxide layers 84 and 88 slightly exceeds the total thickness for the corresponding layer to act as work functions. Accordingly, ruthenium oxide layers 82, 86, and 90 and silicon oxide layers 84 and 88 collectively form the work-function layer of the resulting transistor. The subsequently formed filling-regions 94 (FIG. 14) is not a work-function layer, and does not affect the work function of the resulting gate stacks.

In accordance with some embodiments, in device region 300-S, the recesses 74 between horizontally spaced semiconductor nanostructures 26′ may be fully filled. In device region 300-L, on the other hand, the recesses 74 between horizontally spaced semiconductor nanostructures 26′ may still have some portions left unfilled.

In the deposition of the ruthenium oxide layers 82, 86, and 90 and the soaking process for forming silicon oxide layers 84 and 88, wafer 2 may be heated, for example, to a temperature in a range between about 100° C. and about 500° C.

After the formation of ruthenium oxide layer 90, a thermal anneal process 92 is performed. The respective process is illustrated as process 230 in the process flow 200 as shown in FIG. 26. The thermal anneal process 92 may be performed through furnace anneal, rapid thermal anneal, or the like. When furnace anneal is performed, the anneal duration may be in the range between about 10 milliseconds and about 300 seconds. The temperature may be in the range between about 100° C. and about 500° C. The anneal process 92 has the function of redistributing oxygen within the deposited film stack.

In accordance with some embodiments, the anneal process 92 causes inter-diffusion of ruthenium, oxygen, and silicon. Accordingly, each of ruthenium oxide layers 82, 86, and 90 and silicon oxide layers 84 and 88 may comprise ruthenium, oxygen, and silicon, and are conductive.

FIG. 14 illustrates the formation of filling-regions 94. The respective process is illustrated as process 232 in the process flow 200 as shown in FIG. 26. In accordance with some embodiments, filling-regions 94 comprise ruthenium oxide. The formation method may include Chemical Vapor Deposition (CVD), wherein both of the ruthenium precursor and the oxygen-containing precursor may be conducted. The corresponding ruthenium-containing precursor and oxygen-containing precursor may be selected from the same group of candidate precursors for forming ruthenium oxide layers 82, 86, and 90, and are not repeated herein.

In accordance with alternative embodiments, filling-regions 94 comprise elemental ruthenium, which is not a compound. The oxygen-containing precursor is thus not adopted. In accordance with yet alternative embodiments, filling-regions 94 comprise tungsten, cobalt, or the like. The deposition of the ruthenium, tungsten, cobalt, or the like may be through PVD, CVD, or the like.

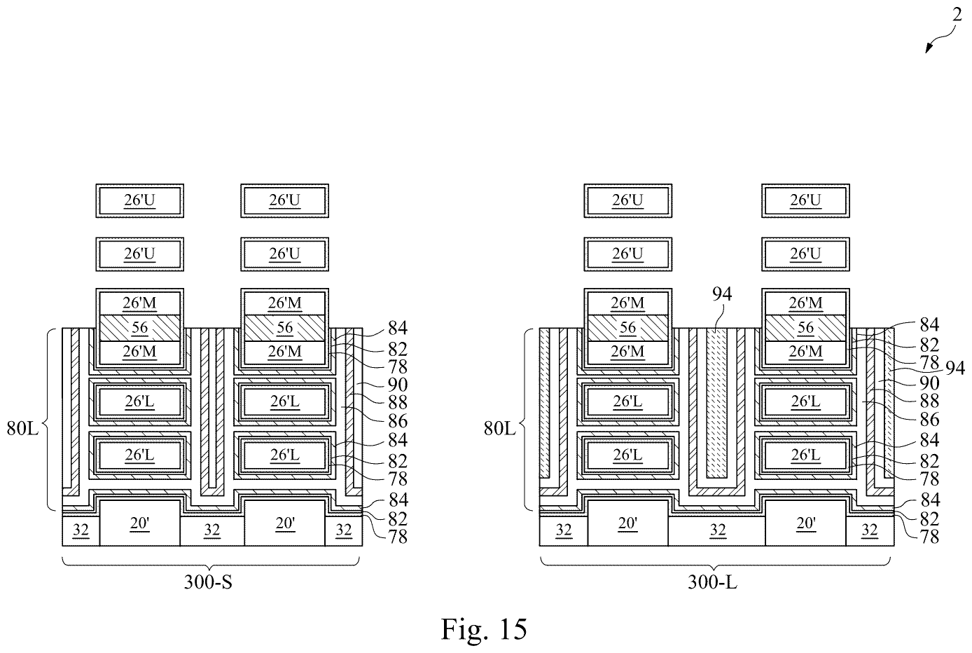

In subsequent processes, a planarization process such as a CMP process or a mechanical grinding process is performed to level the top surface of the deposited layers. An etch-back process is then performed to etch back the deposited layers, until the top surfaces of the deposited layers are lower than the bottom one of the semiconductor nanostructures 26′U. The resulting ruthenium oxide layers 82, 86, and 90, silicon oxide layers 84 and 88, and filling-regions 94 form lower gate electrodes 80L, as shown in FIG. 15. The respective process is illustrated as process 234 in the process flow 200 as shown in FIG. 26.

Ruthenium oxide layer 82, silicon oxide layer 84, ruthenium oxide layer 96, silicon oxide layer 88, and lower portions or all of ruthenium oxide layer 90 collectively form the work-function layers. The CMP process, such as the type of the slurry may be selected to reduce the dishing of the top surfaces of the polished layers. Furthermore, the etching chemicals used in the etch-back process may be selected, so that the top surfaces of ruthenium oxide layer 82, silicon oxide layer 84, ruthenium oxide layer 96, and silicon oxide layer 88, etc. are as planar as possible.

FIGS. 16A and 16B illustrate the formation of upper gate electrodes 80U. The respective process is illustrated as process 236 in the process flow 200 as shown in FIG. 26. In accordance with some embodiments, upper gate electrodes 80U may include n-type work-function layers, which have relatively low work functions, for example, lower than about 4.6 eV. It is appreciated that upper gate electrodes 80U may be electrically connected to the underlying lower gate electrodes 80L, or may be electrically disconnected from the underlying lower gate electrodes 80L, for example, by dielectric layers 102. Dielectric layers 102 are illustrated as being dashed to indicate that they may or may not be formed.

CFET 10 is thus formed, and includes lower FET 10L and upper FET 10U. The lower FET 10L includes gate dielectric 78 and gate electrode 80L, which collectively form gate stack 91L. The upper FET 10U includes gate dielectric 78 and gate electrode 80U, which collectively form gate stack 91U.

Ruthenium oxide is electrically conductive, and has a high work function, for example, in the range between about 5.0 eV and about 5.2 eV, which makes ruthenium oxide a good candidate as the work-function layers of the PFETs. The ruthenium oxide, however, is prone to reduction back to elemental ruthenium, and hence its work function may adversely shift lower. In accordance with some embodiments of the present disclosure, silicon oxide is formed to trap oxygen and to block the oxygen from diffused through. The ruthenium oxide is thus more stable.

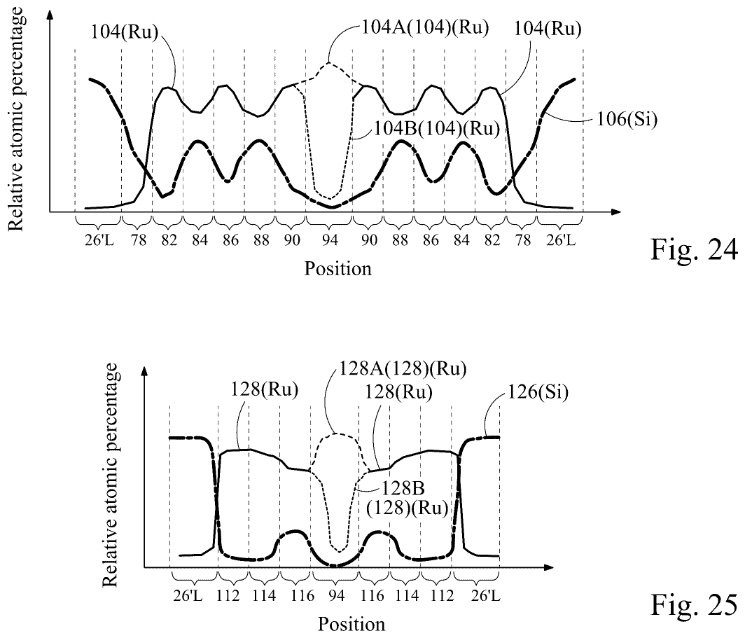

FIG. 24 illustrates a schematic distribution profiles of ruthenium and silicon in accordance with some embodiments. The X-axis represents the positions and the corresponding layers. The Y-axis shows the schematic relative atomic percentages. The profiles are obtained along arrow 122 in FIG. 16A. Line 104 is the profile of ruthenium, and line 106 is the profile of silicon. The peaks of ruthenium may correspond to the valleys of silicon, and vice versa, wherein the peaks of ruthenium are in ruthenium oxide layers 82, 86, and 90, and the peaks of silicon are in the silicon oxide layers 84 and 86. Line 104A is the profile of ruthenium when filling-regions 94 comprise ruthenium or ruthenium oxide, and Line 104B is the profile of ruthenium when filling-regions 94 do not include ruthenium.

The profiles obtained along arrow 122′ in FIG. 16A will be essentially the same as what are shown in FIG. 24, except that the filling-region 94 and the respective profiles no longer exist, and the regions 90 on opposite sides of filling-region 94 (and the respective profiles therein) are merged and are relatively planar in the merged region.

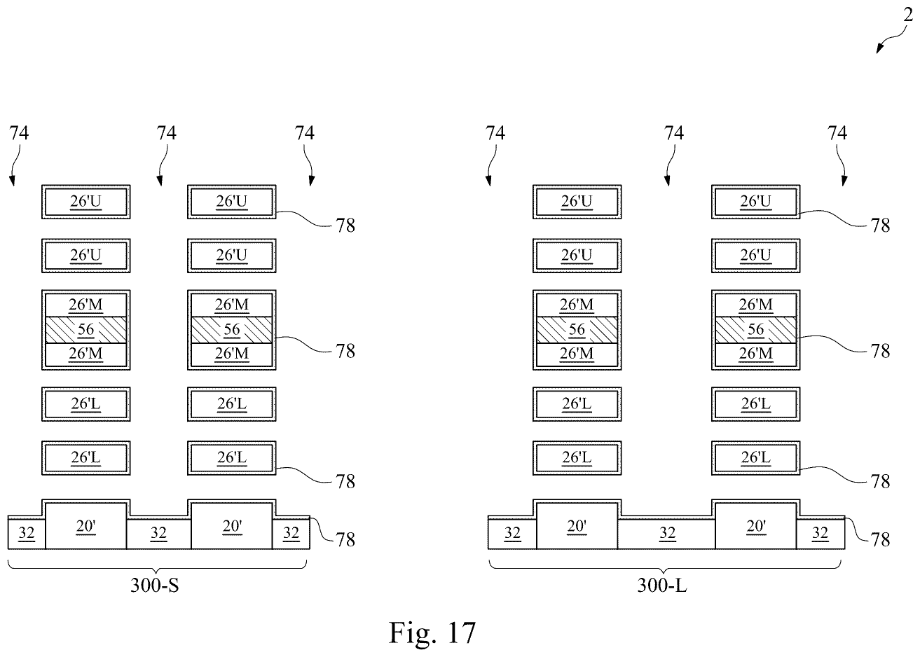

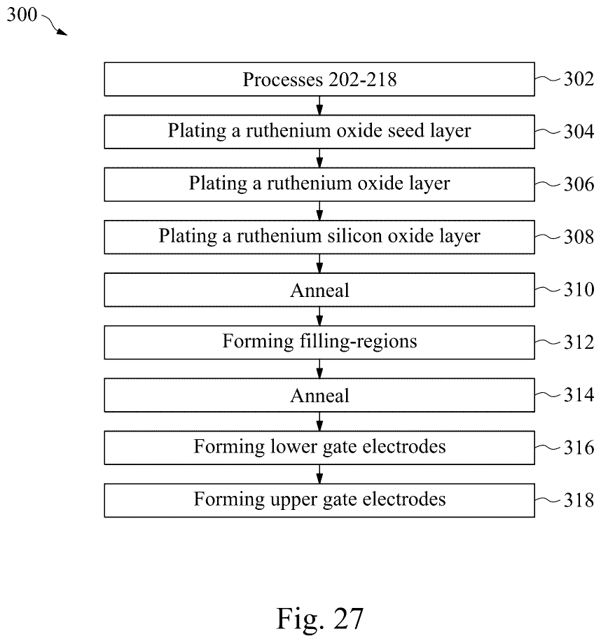

FIGS. 17-23 illustrate the cross-sectional views of intermediate stages in the formation of CFETs in accordance with alternative embodiments of the present disclosure. The respective processes are represented by process flow 300 as shown in FIG. 27. These embodiments are similar to the preceding embodiments, except that instead of depositing alternating ruthenium oxide layers and silicon oxide layers, plating processes are performed.

Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

The initial steps and the resulting structure of these embodiments are essentially the same as shown in FIGS. 1-6, 7A, 7B, 8A, and 8B. The respective processes are illustrated as process 302 in the process flow 300 as shown in FIG. 27. Process 302 also includes the processes 202 through 218 in the process flow 200 as shown in FIG. 26. FIG. 17 illustrates a cross-sectional view, which is the same as what is shown in FIG. 8B.

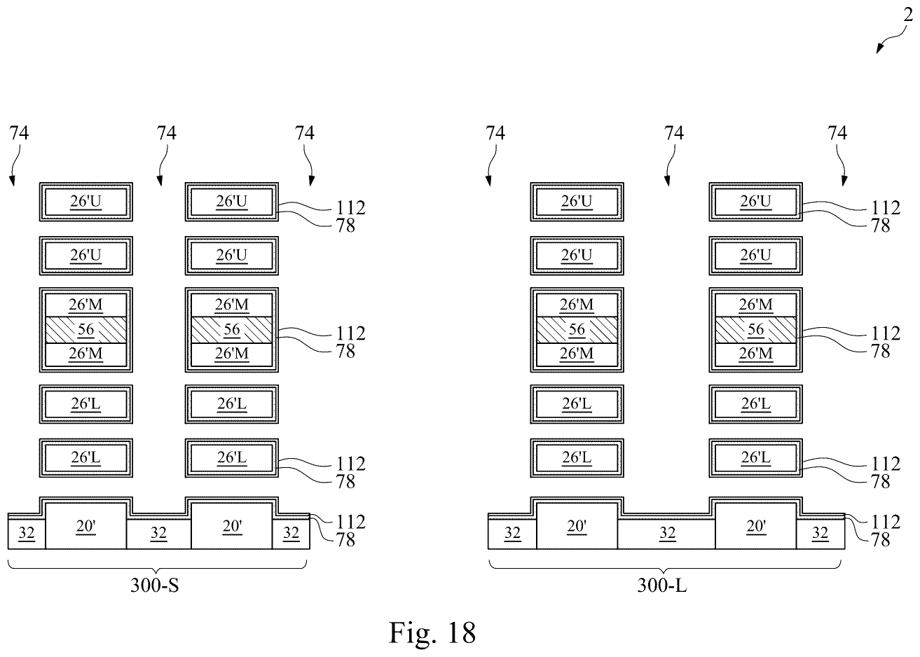

Next, as shown in FIG. 18, ruthenium oxide seed layer 112 is formed. The respective process is illustrated as process 304 in the process flow 300 as shown in FIG. 27. In accordance with some embodiments, the formation process includes a (wet) plating process, wherein a chemical solution is used. The chemical solution comprises water, a ruthenium-containing precursor, and a reduction agent for reducing the ruthenium-containing precursor as ruthenium.

In accordance with some embodiments, the ruthenium-containing precursor may comprise RuCl₃, (Ru(acac)₃), (Ru(NO)(NO₃)₃), Ru₃(CO)₁₂, and/or the like. The reduction agent may comprise hydrazine, NaBH₄, ascorbic acid, or the like. The plating rate, which is the increase thickness of ruthenium oxide seed layer 112 per unit time, is controlled to be small enough, so that ruthenium oxide seed layer 112 may be formed as a conformal layer with a high uniformity. If the plating rate is too high, there may be locations that no ruthenium oxide seed layer 112 is formed. For example, the deposition rate may be smaller than about 20 Å/minute. The reduction of the deposition rate may be achieved by controlling the weight percentage of the ruthenium-containing precursor to be small, for example, smaller than about 20 percent. Ruthenium oxide seed layer 112 does not have silicon doped therein. Otherwise, the doped silicon will adversely affect the seeding.

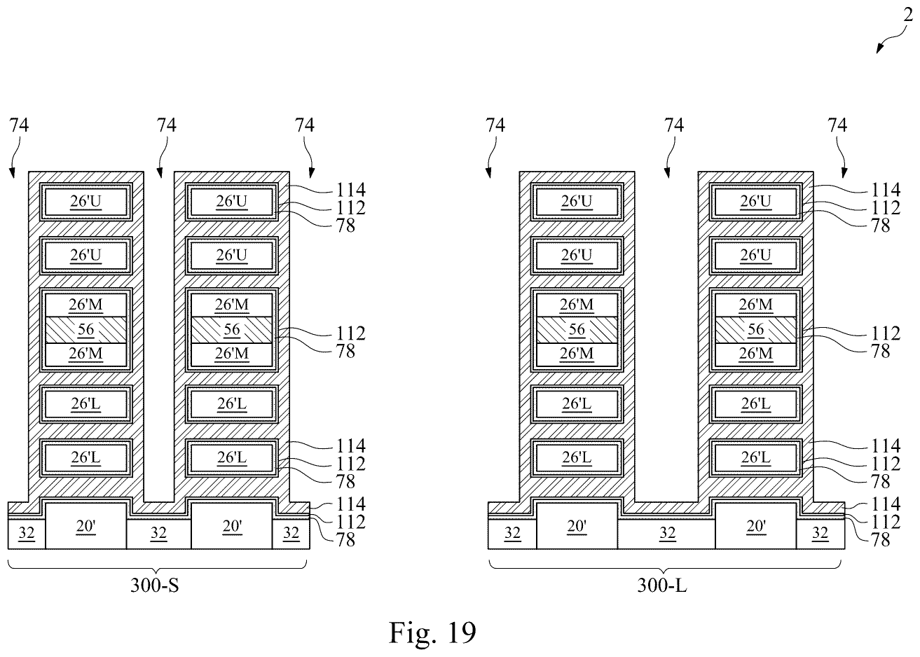

Referring to FIG. 19, ruthenium oxide layer 114 is formed. The respective process is illustrated as process 306 in the process flow 300 as shown in FIG. 27. In accordance with some embodiments, the formation process also includes a plating process, wherein a chemical solution is used. The chemical solution also comprises water, a ruthenium-containing precursor, and a reduction agent for reducing the ruthenium-containing precursor as ruthenium. The ruthenium-containing precursor and the reduction agent may be selected from the same group of candidate precursors for plating ruthenium oxide seed layer 112.

Since ruthenium oxide seed layer 112 is a conformal layer with good uniformity, ruthenium oxide layer 114 may be plated faster without scarifying film quality. The plating rate of ruthenium oxide layer 114 is greater than the ruthenium oxide seed layer 112, for example, with a plating rate ratio of the plating rate of ruthenium oxide layer 114 to the plating rate of ruthenium oxide seed layer 112 being greater than 2. The plating ratio may also be in the range between about 2 and about 10. The increase in the depositing rate may be achieved by increasing the weight percentage of the ruthenium-containing precursor, for example, to be greater than about 100 percent.

Ruthenium oxide layer 114 also may not have silicon doped therein. Otherwise, since ruthenium oxide layer 114 is close to the channel, the performance of the resulting transistor may be adversely affected by the doped silicon.

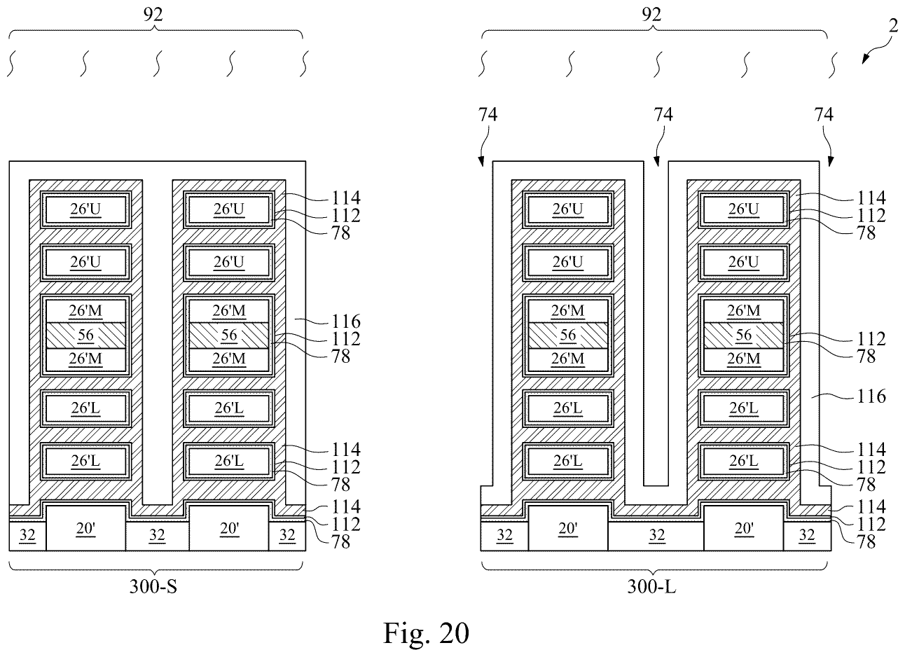

Referring to FIG. 20, ruthenium silicon oxide layer 116 is deposited. The respective process is illustrated as process 308 in the process flow 300 as shown in FIG. 27. In accordance with some embodiments, ruthenium silicon oxide layer 116 is deposited through plating, wherein a chemical solution is used. The chemical solution comprises water, a ruthenium-containing precursor, a silicon-containing precursor, and a reduction agent for reducing the ruthenium-containing precursor into ruthenium.

The ruthenium-containing precursor and the reduction agent may be selected from the same group of (and may be the same as or different from) candidate materials for plating ruthenium oxide seed layer 112 and ruthenium oxide layer 114. The silicon-containing precursor may include Tetraethyl orthosilicate (TEOS), TMOS Si(OCH₃)₄), trimethylsilane (TMS, (CH₃)₃SiH), and/or the like, which may be dissolved in water.

In accordance with these embodiments, ruthenium oxide seed layer 112, ruthenium oxide layer 114, and at least the lower part of ruthenium silicon oxide layer 116 collectively form a work-function layer of the resulting transistor. The silicon in the ruthenium silicon oxide layer 116 exists in the form of silicon oxide, which has the function of trapping oxygen, so that the ruthenium oxide in the ruthenium silicon oxide layer 116 will not be reduced to elemental ruthenium, which has lower work function than ruthenium oxide.

In accordance with some embodiments, in device region 300-S, the gaps between horizontally spaced semiconductor nanostructures 26′ may be fully filled by ruthenium silicon oxide layer 116. In device region 300-L, on the other hand, the gaps between horizontally spaced semiconductor nanostructures 26′ may still have some portions left.

FIG. 20 further illustrates the anneal process 92, which is used to densify the ruthenium oxide seed layer 112, ruthenium oxide layer 114, and ruthenium silicon oxide layer 116. The respective process is illustrated as process 310 in the process flow 300 as shown in FIG. 27. The process conditions of the anneal process 92 may be essentially the same as discussed referring to FIG. 13, and are not repeated herein.

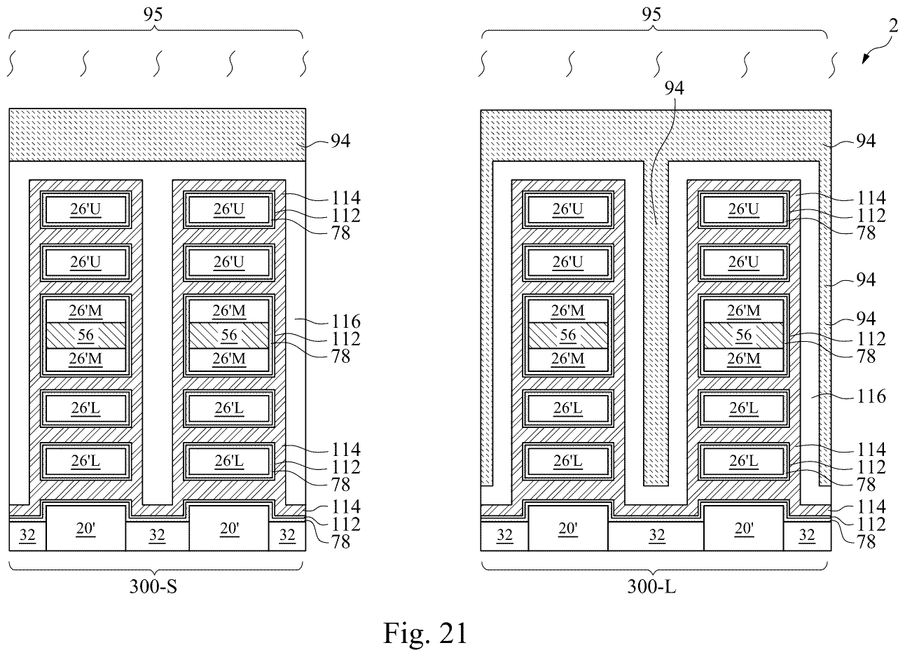

FIG. 21 illustrates the deposition of filling-regions 94. The respective process is illustrated as process 312 in the process flow 300 as shown in FIG. 27. The material and the formation process may be essentially the same as discussed referring to FIG. 14, and hence is not repeated herein. Filling-regions 94 are farther from the channels of the respective transistors than the distance to act as work-function layers, and thus are not work-function layers.

Next, as further illustrated in FIG. 21, an anneal process 95, which may be performed in a forming gas (such as the mixture of H₂ and N₂), is performed. The respective process is illustrated as process 314 in the process flow 300 as shown in FIG. 27. The anneal duration may be in the range between about 60 seconds and about 600 seconds. The temperature may be in the range between about 150° C. and about 500° C. The anneal process 95 also has the function of densify the deposited layers.

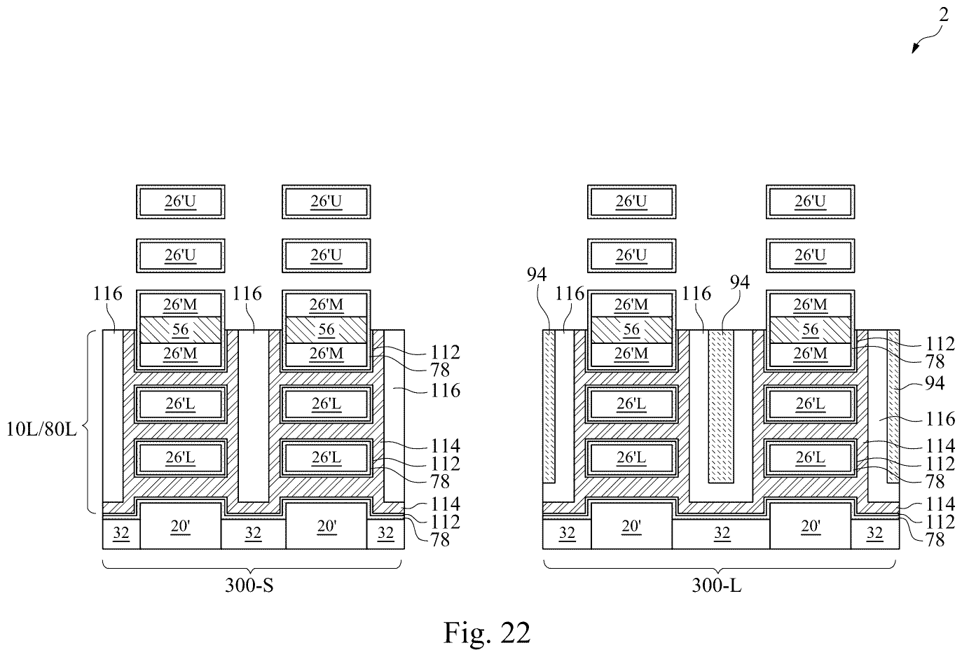

FIG. 22 illustrates the planarization and the recessing of the deposited materials, thus forming lower gate electrode 81L, which includes ruthenium oxide seed layer 112, ruthenium oxide layer 114, ruthenium silicon oxide layer 116, and filling-regions 94. The respective process is illustrated as process 316 in the process flow 300 as shown in FIG. 27.

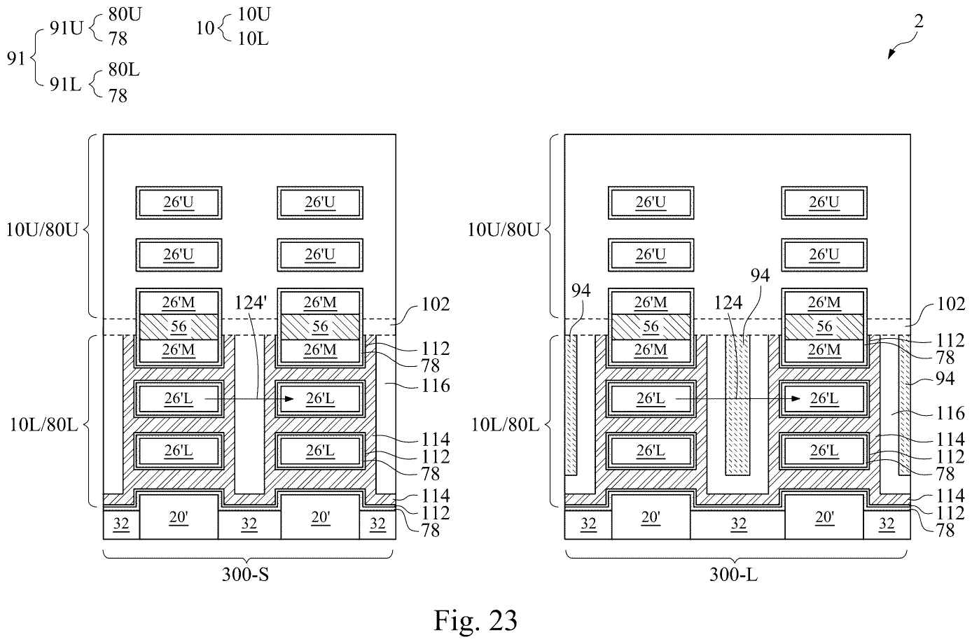

FIG. 23 illustrates the formation of upper electrode 81U and possible dielectric layer 102 (if any). The respective process is illustrated as process 318 in the process flow 300 as shown in FIG. 27. CFET 10 is thus formed.

FIG. 25 illustrates the schematic distribution profiles of ruthenium and silicon in accordance with some embodiments. The X-axis represents the position and the corresponding layers. The Y-axis shows the schematic relative atomic percentages. The profiles are obtained along arrow 124 in FIG. 23. Line 128 is the profile of ruthenium, and line 126 is the profile of silicon. Line 128 may include 128-A or 128-B, depending on whether filling-regions 94 comprise ruthenium or not. Line 128A is the profile of ruthenium when filling-regions 94 comprise ruthenium or ruthenium oxide, and Line 128B is the profile of ruthenium when filling-regions 94 do not include ruthenium.

The profiles obtained along arrow 124′ in FIG. 23 will be essentially the same as what are shown in FIG. 25, except that the filling-region 94 and the respective profiles therein no longer exist, and the regions 116 (and the corresponding profiles therein) on opposite sides of filling-region 94 (and the respective profiles therein) are merged.

The embodiments of the present disclosure have some advantageous features. By doping silicon (and silicon oxide) in ruthenium oxide, the oxygen is better trapped in the ruthenium oxide, and thus ruthenium oxide is more stable. Since the work function of the ruthenium oxide is high, the performance of the resulting PFETs may be improved, and the stability of the PFETs is maintained.

In accordance with some embodiments of the present disclosure, a method includes forming a semiconductor region; forming a gate spacer over the semiconductor region; forming a source/drain region aside of the semiconductor region, wherein the source/drain region is of p-type; forming a gate dielectric over the semiconductor region, wherein the gate dielectric is formed in a space between opposing portions of the gate spacer; forming a first ruthenium oxide layer, wherein the first ruthenium oxide layer is over the gate dielectric, and wherein the first ruthenium oxide layer acts as a part of a work-function layer of a gate electrode; and incorporating silicon into the first ruthenium oxide layer.

In an embodiment, the incorporating the silicon into the first ruthenium oxide layer comprises: depositing a first silicon oxide layer over and contacting the first ruthenium oxide layer; and performing an annealing process. In an embodiment, the method further comprises depositing a second ruthenium oxide layer over the first silicon oxide layer. In an embodiment, the method further comprises depositing a second silicon oxide layer over the second ruthenium oxide layer.

In an embodiment, the depositing the first silicon oxide layer comprises soaking a wafer that comprises the first ruthenium oxide layer in a silicon-containing gas. In an embodiment, the soaking the wafer is performed in a chamber that is connected to open air. In an embodiment, the forming the first ruthenium oxide layer comprises a plating process, wherein the incorporating the silicon into the first ruthenium oxide layer comprises: co-plating silicon when the first ruthenium oxide layer is plated.

In an embodiment, the method further comprises depositing a conductive gap-filling region over the first ruthenium oxide layer, wherein the conductive gap-filling region comprises elemental ruthenium. In an embodiment, the method further comprises depositing a conductive gap-filling region over the first ruthenium oxide layer, wherein the conductive gap-filling region comprises ruthenium oxide. In an embodiment, the first ruthenium oxide layer and the source/drain region are comprised in a lower transistor, and the method further comprising forming an upper transistor overlapping the lower transistor.

In accordance with some embodiments of the present disclosure, a method includes forming a plurality of semiconductor layers, with upper ones of the plurality of semiconductor layers overlapping corresponding lower ones of the plurality of semiconductor layers; forming gate dielectrics encircling the plurality of semiconductor layers; depositing a first ruthenium oxide layer comprising a plurality of portions over the gate dielectrics; depositing a first silicon oxide layer over the first ruthenium oxide layer; depositing a second ruthenium oxide layer over the first silicon oxide layer; and planarizing the second ruthenium oxide layer, the first silicon oxide layer, and the first ruthenium oxide layer, wherein remaining portions of the second ruthenium oxide layer, the first silicon oxide layer, and the first ruthenium oxide layer form parts of a first gate electrode of a transistor.

In an embodiment, the method further comprises, after the second ruthenium oxide layer is formed, performing an annealing process. In an embodiment, the method further comprises depositing a second silicon oxide layer over the second ruthenium oxide layer. In an embodiment, the method further comprises depositing a third ruthenium oxide layer over the second silicon oxide layer. In an embodiment, the method further comprises depositing a ruthenium layer over the second ruthenium oxide layer. In an embodiment, the depositing the first silicon oxide layer comprises soaking the first ruthenium oxide layer in a silicon-comprising process gas and an oxygen-comprising process gas.

In accordance with some embodiments of the present disclosure, a structure comprising: a first transistor comprising: a semiconductor region; a gate spacer over the semiconductor region a gate dielectric over the semiconductor region and between opposing portions of the gate spacer; a gate electrode comprising: a first ruthenium oxide layer over the gate dielectric, wherein the first ruthenium oxide layer comprises silicon therein; and a first source/drain region aside of the gate spacer. In an embodiment, the structure further comprises a silicon oxide layer contacting the first ruthenium oxide layer.

In an embodiment, the structure further comprises a second ruthenium oxide layer between the first ruthenium oxide layer and the semiconductor region, wherein the second ruthenium oxide layer has a lower silicon atomic percentage than the first ruthenium oxide layer. In an embodiment, the structure further comprises a second transistor overlapping the first transistor, wherein the first transistor is a p-type transistor, and the second transistor is an n-type transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a semiconductor region;
forming a gate spacer over the semiconductor region;
forming a source/drain region aside of the semiconductor region, wherein the source/drain region is of p-type;
forming a gate dielectric over the semiconductor region, wherein the gate dielectric is formed in a space between opposing portions of the gate spacer;
forming a first ruthenium oxide layer, wherein the first ruthenium oxide layer is over the gate dielectric, and wherein the first ruthenium oxide layer acts as a part of a work-function layer of a gate electrode; and
incorporating silicon into the first ruthenium oxide layer.

2. The method of claim 1, wherein the incorporating the silicon into the first ruthenium oxide layer comprises:
depositing a first silicon oxide layer over and contacting the first ruthenium oxide layer; and
performing an annealing process.

3. The method of claim 2 further comprising depositing a second ruthenium oxide layer over the first silicon oxide layer.

4. The method of claim 3 further comprising depositing a second silicon oxide layer over the second ruthenium oxide layer.

5. The method of claim 2, wherein the depositing the first silicon oxide layer comprises soaking a wafer that comprises the first ruthenium oxide layer in a silicon-containing gas.

6. The method of claim 5, wherein the soaking the wafer is performed in a chamber that is connected to open air.

7. The method of claim 1, wherein the forming the first ruthenium oxide layer comprises a plating process, wherein the incorporating the silicon into the first ruthenium oxide layer comprises:
co-plating silicon when the first ruthenium oxide layer is plated.

8. The method of claim 1 further comprising:
depositing a conductive gap-filling region over the first ruthenium oxide layer, wherein the conductive gap-filling region comprises elemental ruthenium.

9. The method of claim 1 further comprising:
depositing a conductive gap-filling region over the first ruthenium oxide layer, wherein the conductive gap-filling region comprises ruthenium oxide.

10. The method of claim 1, wherein the first ruthenium oxide layer and the source/drain region are comprised in a lower transistor, and the method further comprising forming an upper transistor overlapping the lower transistor.

11. A method comprising:
forming a plurality of semiconductor layers, with upper ones of the plurality of semiconductor layers overlapping corresponding lower ones of the plurality of semiconductor layers;
forming gate dielectrics encircling the plurality of semiconductor layers;
depositing a first ruthenium oxide layer comprising a plurality of portions over the gate dielectrics;
depositing a first silicon oxide layer over the first ruthenium oxide layer;
depositing a second ruthenium oxide layer over the first silicon oxide layer; and
planarizing the second ruthenium oxide layer, the first silicon oxide layer, and the first ruthenium oxide layer, wherein remaining portions of the second ruthenium oxide layer, the first silicon oxide layer, and the first ruthenium oxide layer form parts of a first gate electrode of a transistor.

12. The method of claim 11 further comprising, after the second ruthenium oxide layer is formed, performing an annealing process.

13. The method of claim 11 further comprising:
depositing a second silicon oxide layer over the second ruthenium oxide layer.

14. The method of claim 13 further comprising:
depositing a third ruthenium oxide layer over the second silicon oxide layer.

15. The method of claim 11 further comprising depositing a ruthenium layer over the second ruthenium oxide layer.

16. The method of claim 11, wherein the depositing the first silicon oxide layer comprises soaking the first ruthenium oxide layer in a silicon-comprising process gas and an oxygen-comprising process gas.

17. A structure comprising:
a first transistor comprising:
a semiconductor region;
a gate spacer over the semiconductor region
a gate dielectric over the semiconductor region and between opposing portions of the gate spacer;
a gate electrode comprising:
a first ruthenium oxide layer over the gate dielectric, wherein the first ruthenium oxide layer comprises silicon therein; and
a first source/drain region aside of the gate spacer.

18. The structure of claim 17 further comprising a silicon oxide layer contacting the first ruthenium oxide layer.

19. The structure of claim 17 further comprising a second ruthenium oxide layer between the first ruthenium oxide layer and the semiconductor region, wherein the second ruthenium oxide layer has a lower silicon atomic percentage than the first ruthenium oxide layer.

20. The structure of claim 17 further comprising a second transistor overlapping the first transistor, wherein the first transistor is a p-type transistor, and the second transistor is an n-type transistor.
